(19) United States
(12) Patent Application Publication
(10) Pub. No.: US 2015/0364475 A1
(43) Pub. Date: Dec. 17, 2015

(54) SEMICONDUCTOR DEVICE AND METHOD FOR PRODUCING SAME

(71) Applicant: Yasushi Yamazaki, Tokyo (JP)

(72) Inventor: Yasushi Yamazaki, Tokyo (JP)

(21) Appl. No.: 14/762,527

(22) PCT Filed: Jan. 17, 2014
(86) PCT No.: PCT/JP2014/050747

§ 371 Date: Jul. 22, 2015

(30) Foreign Application Priority Data
Jan. 28, 2013 (JP) 2013-013242

(51) Int. Cl. H01L 27/108; H01L 29/08; H01L 29/423; H01L 27/02; H01L 29/06

(52) U.S. Cl. CPC H01L 27/10823; H01L 27/10814; H01L 27/0207; H01L 27/10876; H01L 29/0649; H01L 29/4236; H01L 29/0847

(57) ABSTRACT

One semiconductor device includes a plurality of first element-separating regions formed on a semiconductor substrate so as to extend along a first direction (Y direction), a plurality of second element-separating regions formed so as to extend along a second direction (X direction) that intersects with the first direction (Y direction), a plurality of active regions insulated and separated by the first element-separating regions and the second element-separating regions a plurality of gate electrodes (word lines) formed so as to extend along the first direction (Y direction), and an embedded diffusion layer that is formed in a position deeper than the first element-separating regions and the second element-separating regions, and that has an inverse characteristic to the active regions.

### TECHNICAL FIELD

The present invention relates to a semiconductor device and a method of manufacturing the same.

### BACKGROUND ART

The dimensions of transistors have tended to decrease in recent years as semiconductor elements have become miniaturized, and this reduction in the dimensions has led to more pronounced short channel effects. For example, in a DRAM (Dynamic Random Access Memory) or the like, a reduction in the memory cell dimensions leads to a reduction in the channel length of the transistor, resulting in problems such as a deterioration in the performance of the transistor and a worsening in the memory cell retention and write characteristics.

Accordingly, in order to resolve such problems, recess (trench) type FETs (Field Effect Transistors) in which the channel is formed as a three-dimensional structure by forming grooves (trenches) in a semiconductor substrate, and fin-type FETs in which the channel is formed as a three-dimensional structure by forming fins between the grooves, have, for example, been developed (see, for example, Japanese Patent Kokai 2005-064500 (patent literature article 1), Japanese Patent Kokai 2007-027753 (patent literature article 2), and Japanese Patent Kokai 2007-305827 (patent literature article 3)).

More specifically, in a trench-type FET a groove is formed in a semiconductor substrate, and a gate electrode is formed in the groove with the interposition of a gate insulating film, thereby forming the channel as a three-dimensional structure. Meanwhile, in a fin-type FET, a gate electrode is formed with the interposition of a gate insulating film in such a way as to straddle a fin which protrudes out from between grooves formed in a semiconductor substrate, thereby forming the channel as a three-dimensional structure. In both cases the gate width can be increased relative to the channel width, and short channel effects can therefore be suppressed.

Further, in DRAMs, concomitant with reductions in the memory cell dimensions, consideration has also been given to adopting, as selection transistors which are a constituent of the memory cells, embedded-gate transistors in which the gate electrode is embedded in the surface layer of a semiconductor substrate.

With such an embedded-gate transistor, because the gate electrode (word line) is embedded in the surface layer of the semiconductor substrate, the gate electrode does not protrude upward further than the substrate surface, and from among the wiring lines that are connected to the memory cells, the only wiring lines that are located in the upper layer of the semiconductor substrate are the bit lines. Thus when capacitors, contact plugs and the like which form memory cells are to be formed on the semiconductor substrate, the arrangement thereof is simple, in addition to which there is also the advantage that processing difficulties can be alleviated.

FIG. 43 of Japanese Patent Kokai 2012-134439 (patent literature article 4) describes disturb failure between adjacent cells, which occurs when the abovementioned embedded gate type transistor is employed. Here, disturb failure is a phenomenon whereby the On-Off operation of a cell transistor results in the generation of electric charge that cannot be absorbed, this charge flows into an adjacent cell which shares a bit contact plug, and the data held by the adjacent cell is destroyed.

### PATENT LITERATURE

Patent literature article 1: Japanese Patent Kokai 2005-064500
Patent literature article 2: Japanese Patent Kokai 2007-027753
Patent literature article 3: Japanese Patent Kokai 2007-305827
Patent literature article 4: Japanese Patent Kokai 2012-134439

### SUMMARY OF THE INVENTION

### Problems to be Resolved by the Invention

However, in the embedded-gate transistor discussed hereinabove, it is known that by employing a metal wiring line layer such as W/TiN as the gate electrode (word line) embedded in the surface layer of the semiconductor substrate, it is possible to obtain advantages such as reducing the word line capacitance and the bit line capacitance, suppressing a current known as the GIDL (Gate-Induced-Drain-Leakage current), improving the retention characteristics, and reducing the current consumption (IDD5).

Further, it is also effective to improve the retention time (tREF) by carrying out localized channel ion implantation known as LCI (Local Channel Implant) after the embedded gate groove portions have been formed, in order to alleviate the junction field (Esn) on the storage node (capacitor contact) side.

Here, if the pitch spacing between adjacent word lines (referred to as the WL-Pitch hereinafter) is reduced, this leads to a reduction in the threshold voltage (Vt1), and in order to control this reduction it is necessary to increase the B concentration used to control the threshold. The junction field (Esn) on the storage node side rises as a result, and this is liable to cause the retention time (tREF) to decrease even if the capacitance of the storage node capacitor remains constant.

Further, as illustrated in FIG. 9, if the WL-Pitch decreases, then in a first cell transistor 4A and a second cell transistor 4B which share a bit line 501 in a memory cell active region 101 formed by demarcating a semiconductor substrate 100 using element isolation regions 200, an On-Off operation of the first cell transistor 4A causes an electric charge e− to be ejected from a channel 7A of the first cell transistor 4A, this charge penetrates into a channel 7B of the second cell transistor 4B, passes through a capacitor contact 700 and generates a disturb failure whereby the stored information in a capacitor, which is not shown in the drawing, is destroyed.

In order to prevent this, additional measures must be taken, such as increasing the controllability of the threshold in the gate electrode by introducing additional boron (B) used to control the threshold, or adopting a fin construction for the bottom surface of the embedded gate groove portion. Further, the impact of these circumstances is predicted to increase as device miniaturization progresses.

The present invention resolves the problems in the abovementioned prior art, and provides a semiconductor device capable of preventing disturb failure even if device miniaturization progresses, and a method of manufacturing the same.

### Means of Overcoming the Problems

A semiconductor device according to the present invention is characterized in that it comprises:

a plurality of first element isolation regions formed extending in a first direction on
a semiconductor substrate;
a plurality of second element isolation regions formed extending in a second direction which intersects the first direction;
a plurality of active regions which are insulated and isolated by means of the first element isolation regions and the second element isolation regions;
a plurality of gate electrodes formed extending in the first direction; and
a first embedded diffusion layer which is formed in a location that is deeper than the first element isolation regions and the second element isolation regions, and which has the opposite characteristic to the active regions.

Further a method of manufacturing a semiconductor device according to the present invention is characterized in that:

a plurality of first groove portions for element isolation are formed extending in a first direction on a semiconductor substrate;
a plurality of first element isolation regions are formed by embedding first element isolation insulating films into the first groove portions;
a plurality of second groove portions for element isolation are formed extending in a second direction which intersects the first direction;
a plurality of second element isolation regions are formed by embedding second element isolation insulating films into the second groove portions;
a plurality of active regions which are insulated and isolated in the first direction and the second direction by means of the first element isolation regions and the second element isolation regions are formed;
a plurality of groove portions for embedded gates are formed extending in the first direction;
gate electrodes are embedded in the groove portions for the embedded gates, with the interposition of gate insulating films; and
a first embedded diffusion layer having the opposite characteristic to the active regions is formed in a location that is deeper than the first element isolation regions and the second element isolation regions.

### Advantages of the Invention

According to the present invention, disturb failure can be prevented even if device miniaturization progresses.

### BRIEF EXPLANATION OF THE DRAWINGS

FIG. 1A is a plan view used to describe the structure of a semiconductor device according to a first mode of embodiment of the present invention.

FIG. 1B is a drawing used to describe the structure of the semiconductor device according to the first mode of embodiment of the present invention, being a cross-sectional view through A-A in FIG. 1A.

FIG. 2 is a cross-sectional view used to describe a step in the manufacture of the semiconductor device according to the first mode of embodiment of the present invention.

FIG. 3 is a cross-sectional view used to describe a step in the manufacture of the semiconductor device according to the first mode of embodiment of the present invention.

FIG. 4 is a cross-sectional view used to describe a step in the manufacture of the semiconductor device according to the first mode of embodiment of the present invention.

FIG. 5 is a drawing used to describe the structure of a semiconductor device according to a second mode of embodiment of the present invention, where (a) is plan view and (b) is a cross-sectional view through A-A in (a).

FIG. 6 is a drawing used to describe a step in the manufacture of the semiconductor device according to the second mode of embodiment of the present invention, where (a) is plan view and (b) is a cross-sectional view through A-A in (a).

FIG. 7 is a cross-sectional view used to describe a step in the manufacture of the semiconductor device according to the second mode of embodiment of the present invention.

FIG. 8 is a drawing used to describe a step in the manufacture of the semiconductor device according to the second mode of embodiment of the present invention, where (a) is plan view and (b) is a cross-sectional view through A-A in (a).

FIG. 9 is a cross-sectional view used to describe the problems in a semiconductor device in the prior art.

### MODES OF EMBODYING THE INVENTION

Preferred modes of embodiment of the present invention will now be described in detail with reference to the drawings.

It should be noted that for convenience, some of the drawings used in the following explanation illustrate enlargements of characteristic parts, in order to facilitate understanding of the characteristics, and the ratios between the dimensions of various constituent elements, for example, are not necessarily the same as would actually be the case. Further, the materials, dimensions and the like shown by way of example in the following description are examples, and the present invention is not necessarily limited thereto, and they may be suitably modified without deviating from the gist of the present invention.

### First Mode of Embodiment

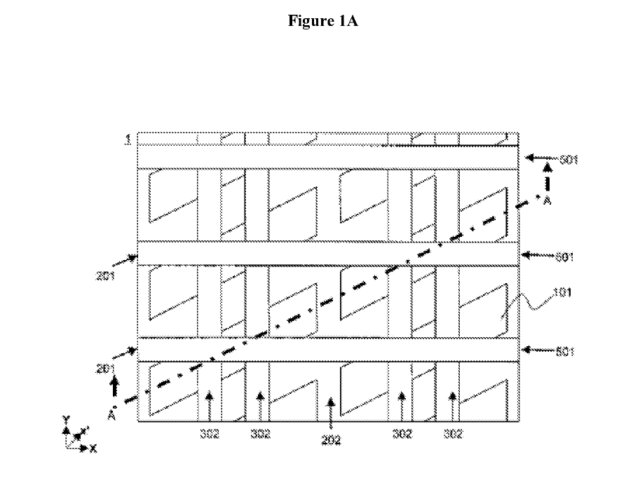

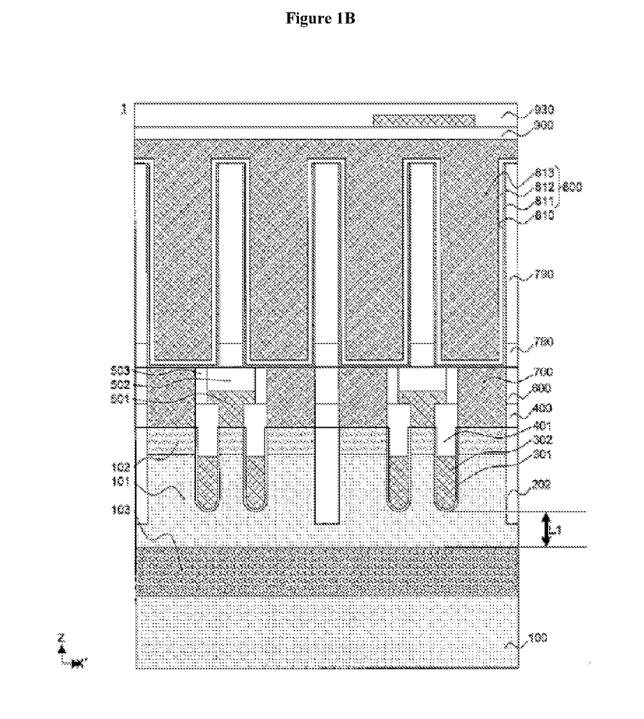

A first mode of embodiment of the present invention will be described with reference to FIG. 1A and FIG. 1B.

The arrangement of the main parts of a semiconductor device 1 to which the present invention has been applied will first be described with reference to FIG. 1A and FIG. 1B. It should be noted that FIG. 1A is a plan view illustrating the arrangement of the main parts of the semiconductor device 1 as far as the bit lines. Further, FIG. 1B is a drawing corresponding to a cross-section through A-A in FIG. 1A.

The semiconductor device 1 ultimately functions as a DRAM, and it is provided, within the plane of a semiconductor substrate 100, with a memory cell region and a peripheral circuit region located at the periphery of the memory cell region. Of these, the memory cell region is a region in which a plurality of memory cells are disposed aligned in a matrix formation. Meanwhile, the peripheral circuit region is a region in which circuits for controlling the operation of each memory cell are formed.

A plurality of first element isolation regions 201 known as STIs (Shallow Trench Isolations) and a plurality of second element isolation regions 202 known as STIs are provided in a lattice formation by forming a plurality of groove portions for element isolation, extending in the X-direction in such a way as to divide the surface of the semiconductor substrate 100, and embedding element isolation insulating films into the plurality of groove portions, and forming a plurality of groove portions for element isolation, extending in the Y-direction in such a way as to divide the surface of the semiconductor substrate 100, and embedding element isolation insulating films into the plurality of groove portions, and a plurality of memory cell active regions 101, insulated and isolated by means of the first element isolation regions 201 and the second element isolation regions 202, are provided aligned in the X-direction and the Y-direction, in the parts corresponding to the eyes of the lattice.

Further, a first interlayer insulating film 400 is provided on the surface of the semiconductor substrate 100, and a plurality of word lines 302 extending in the Y-direction which intersects the first element isolation regions 201 and the memory cell active regions 101 are provided aligned in the form of stripes. The word lines 302 are formed by embedding a conductive material, with the interposition of a memory cell gate insulating film 301, in word trenches formed in the first element isolation regions 201 and the memory cell active regions 101, and the upper portions of the word lines 302 are sealed using cap insulating films 401. The conductive material may be polysilicon or a metal such as tungsten.

Further, an impurity having the opposite characteristic to the memory cell active regions 101 is introduced by injection into the memory cell active regions 101 at a depth L1 (for example 300 nm) below the lower ends of the word lines 302, to provide an embedded diffusion layer 103. The embedded diffusion layer 103 is depicted in such a way that it is disposed across the entire memory cell region 2, including below the first element isolation regions 201 and the second element isolation regions 202, but it may also be disposed below only the memory cell active regions 101. By this means, electric charge ejected from the channels is absorbed by the embedded diffusion layer 103. To elaborate, variations in the threshold voltage can be reduced even if the pitch spacing between adjacent gate electrodes (word lines 302) is reduced, and further miniaturization can therefore be supported.

Further, memory cell source/drain diffusion layers 102 (impurity-diffused layers) functioning as the source or the drain of selection transistors are provided in the memory cell active region 101 on both sides of each word line 302. As the memory cell source/drain diffusion layers 102, impurity-diffused layers are formed by ion implantation in a central portion of each memory cell active region 101, sandwiched between the word lines 302, and in both end portions of each memory cell active region 101.

Bit lines 501 are provided in such a way as to be connected to the upper surfaces of the memory cell source/drain diffusion layers 102 in the central portion of each memory cell active region 101, sandwiched between the word lines 302. Cover insulating films 502 are provided on the upper surfaces of the bit lines 501, and liner films 503 are provided on the side surfaces of the bit lines 501.

A second interlayer insulating film 600 is provided in the gaps between each two adjacent bit lines 501. Capacitor contact plugs 700 are provided in such a way as to penetrate through the second interlayer insulating film 600 and to be connected to the upper surfaces of the memory cell source/drain diffusion layers 102 in both end portions of each memory cell active region 101, sandwiching the word lines 302.

A stopper film 780 and a third interlayer insulating film 790 are provided in such a way as to cover the entire surface of the semiconductor substrate 100, including the upper surfaces of the capacitor contact plugs 700. Cylinder holes 810 are provided penetrating through the third interlayer insulating film 790 and the stopper film 780, and using the inside surfaces of the cylinder holes 810, capacitors 800 comprising lower electrodes 811, capacitative insulating films 812 and an upper electrode 813 are provided. It should be noted that the capacitors 800 are described as cylinder-type capacitors, but they may be of another type such as crown-type. A fourth interlayer insulating film 900 and a protective insulating film 930 are provided in such a way as to cover the upper surface of the capacitors 800.

It should be noted that in the semiconductor substrate 100 illustrated in FIG. 1A and FIG. 1B, multiple first element isolation regions 201, second element isolation regions 202 and memory cell active regions 101 are in practice formed in alignment, but in FIG. 1A and FIG. 1B the portion required to provide a description is illustrated schematically in an enlarged state, for convenience.

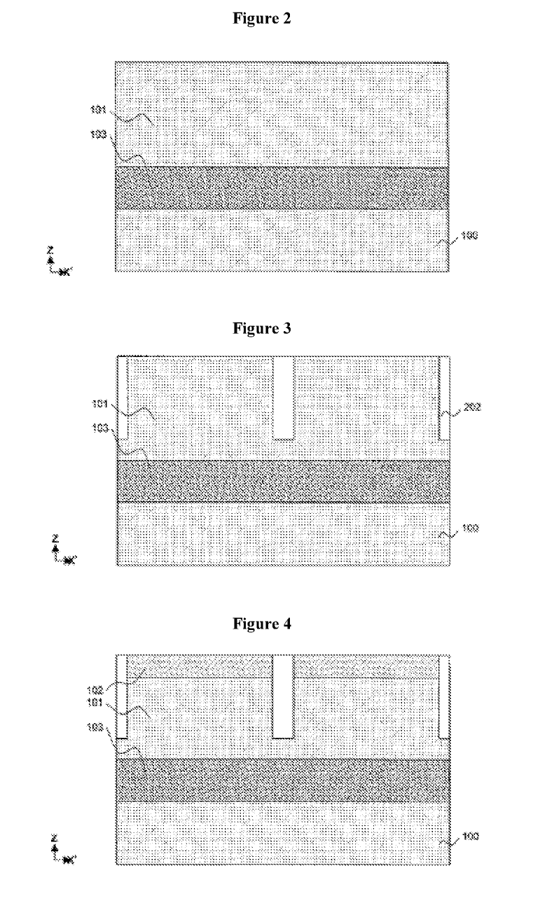

A method of manufacturing the semiconductor device 1 in the first mode of embodiment will now be described with reference to FIG. 2 to FIG. 4.

First, as illustrated in FIG. 2, an impurity having the opposite characteristic to the surface of the semiconductor substrate 100 is implanted into a part of the semiconductor substrate 100 that is deep below the surface (for example 480 nm), to form the embedded diffusion layer 103. Here, the upper end of the embedded diffusion layer 103 is adjusted in such a way as to be in a location that is L1 (for example 300 nm) deeper than the lower end of the word lines 302 that are to be formed later. The part of the semiconductor substrate 100 above the embedded diffusion layer 103 subsequently forms the memory cell active region 101.

Next, as illustrated in FIG. 3, a plurality of groove portions for element isolation are formed extending in the X-direction and the Y-direction in such a way as to divide the memory cell active region 101, and by embedding element isolation insulating films into these groove portions, a plurality of first element isolation regions 201 extending in the X-direction and a plurality of second element isolation regions 202 extending in the Y-direction, and a plurality of memory cell active regions 101 insulated and isolated by means of the first element isolation regions 201 and the plurality of second element isolation regions 202 extending in the Y-direction, are formed.

In this mode of embodiment the embedded diffusion layer 103 is first formed by implantation, but the embedded diffusion layer 103 may also be formed below only the memory cell active regions 101 by performing the abovementioned implantation after the first element isolation regions 201 and the second element isolation regions 202 have been formed.

Next, as illustrated in FIG. 4, an impurity having the opposite characteristic to the memory cell source/drain diffusion layer 101 is implanted with a low energy to form the memory cell source/drain diffusion layers 102 in an upper portion of the memory cell active region 101.

Next, the first interlayer insulating film 400 is deposited over the entire surface of the semiconductor substrate 100, and known methods are used to form the word lines 302, the bit lines 502, the second interlayer insulating film 600, the capacitor contact plugs 700, the stopper film 780, the third interlayer insulating film 790, the capacitors 800, the fourth interlayer insulating film 900 and the protective insulating film 930. This completes the semiconductor device 1 illustrated in FIG. 1.

### Second Mode of Embodiment

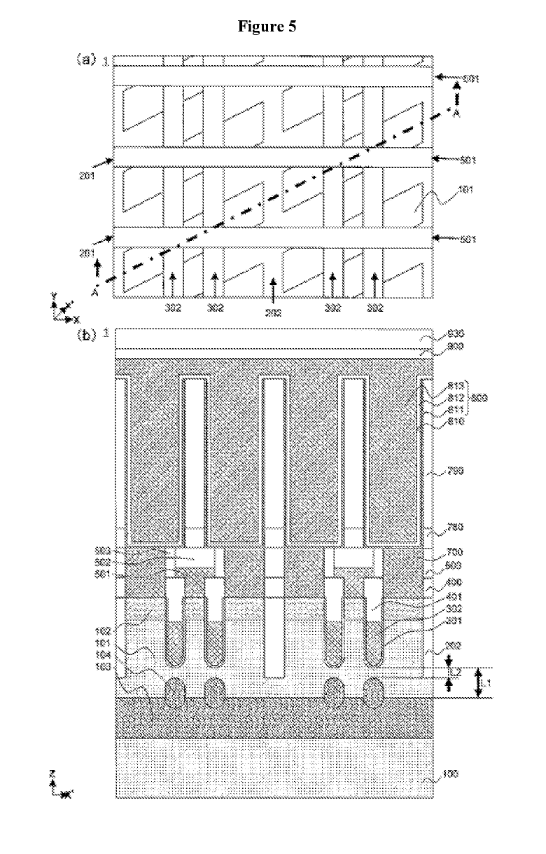

A second mode of embodiment of the present invention will now be described with reference to FIG. 5.

Here, FIG. 5 (a) is a plan view illustrating the arrangement of the main parts of the semiconductor device 1 as far as the bit lines. Further, FIG. 5 (b) is a drawing corresponding to a cross-section through A-A in FIG. 5 (a). Further, in the following description, descriptions of parts that are the same as in the semiconductor device 1 according to the first mode of embodiment illustrated in FIG. 1 are omitted, and the same reference codes are appended in the drawings.

A plurality of first element isolation regions 201 known as STIs and a plurality of second element isolation regions 202 known as STIs are provided in a lattice formation by forming a plurality of groove portions for element isolation, extending in the X-direction in such a way as to divide the surface of the semiconductor substrate 100, and embedding element isolation insulating films into the plurality of groove portions, and forming a plurality of groove portions for element isolation, extending in the Y-direction in such a way as to divide the surface of the semiconductor substrate 100, and embedding element isolation insulating films into the plurality of groove portions, and a plurality of memory cell active regions 101, insulated and isolated by means of the first element isolation regions 201 and the second element isolation regions 202, are provided aligned in the X-direction and the Y-direction, in the parts corresponding to the eyes of the lattice.

Further, a first interlayer insulating film 400 is provided on the surface of the semiconductor substrate 100, and a plurality of word lines 302 extending in the Y-direction which intersects the first element isolation regions 201 and the memory cell active regions 101 are provided aligned in the form of stripes. The word lines 302 are formed by embedding a conductive material, with the interposition of a memory cell gate insulating film 301, in word trenches formed in the first element isolation regions 201 and the memory cell active regions 101, and the upper portions of the word lines 302 are sealed using cap insulating films 401. The conductive material may be polysilicon or a metal such as tungsten.

Further, an impurity having the opposite characteristic to the memory cell active regions 101 is introduced by injection into the memory cell active regions 101 at a depth L1 (for example 300 nm) below the lower ends of the word lines 302, to provide an embedded diffusion layer 103. The embedded diffusion layer 103 is depicted in such a way that it is disposed across the entire memory cell region 2, including below the first element isolation regions 201 and the second element isolation regions 202, but it may also be disposed below only the memory cell active regions 101. By this means, electric charge ejected from the channels is absorbed by the embedded diffusion layer 103. To elaborate, variations in the threshold voltage can be reduced even if the pitch spacing between adjacent gate electrodes (word lines 302) is reduced, and further miniaturization can therefore be supported.

Further, an impurity having the opposite characteristic to the memory cell active regions 101 is introduced by injection, at a concentration that is higher than that of the embedded diffusion layer 103, into the memory cell active regions 101 at a depth L2 (for example 50 nm) below the lower ends of the word lines 302, to provide localized embedded diffusion layers 104. By this means, electric charge ejected from the channels is more readily absorbed by the embedded diffusion layer. In this way, the localized embedded diffusion layers 104 absorb electric charge that was ejected from the channels but was not absorbed by the embedded diffusion layer 103.

Further, memory cell source/drain diffusion layers 102 (impurity-diffused layers) functioning as the source or the drain of selection transistors are provided in the memory cell active region 101 on both sides of each word line 302. As the memory cell source/drain diffusion layers 102, impurity-diffused layers are formed by ion implantation in a central portion of each memory cell active region 101, sandwiched between the word lines 302, and in both end portions of each memory cell active region 101.

Bit lines 501 are provided in such a way as to be connected to the upper surfaces of the memory cell source/drain diffusion layers 102 in the central portion of each memory cell active region 101, sandwiched between the word lines 302. Cover insulating films 502 are provided on the upper surfaces of the bit lines 501, and liner films 503 are provided on the side surfaces of the bit lines 501. A second interlayer insulating film 600 is provided in the gaps between each two adjacent bit lines 501.

Capacitor contact plugs 700 are provided in such a way as to penetrate through the second interlayer insulating film 600 and to be connected to the upper surfaces of the memory cell source/drain diffusion layers 102 in both end portions of each memory cell active region 101, sandwiching the word lines 302. A stopper film 780 and a third interlayer insulating film 790 are provided in such a way as to cover the entire surface of the semiconductor substrate 100, including the upper surfaces of the capacitor contact plugs 700.

Cylinder holes 810 are provided penetrating through the third interlayer insulating film 790 and the stopper film 780, and using the inside surfaces of the cylinder holes 810, capacitors 800 comprising lower electrodes 811, capacitative insulating films 812 and an upper electrode 813 are provided. It should be noted that the capacitors 800 are described as cylinder-type capacitors, but they may be of another type such as crown-type. A fourth interlayer insulating film 900 and a protective insulating film 930 are provided in such a way as to cover the upper surface of the capacitors 800.

It should be noted that in the semiconductor substrate 100 illustrated in FIG. 5, multiple first element isolation regions 201, second element isolation regions 202 and memory cell active regions 101 are in practice formed in alignment, but in FIG. 5 the portion required to provide a description is illustrated schematically in an enlarged state, for convenience.

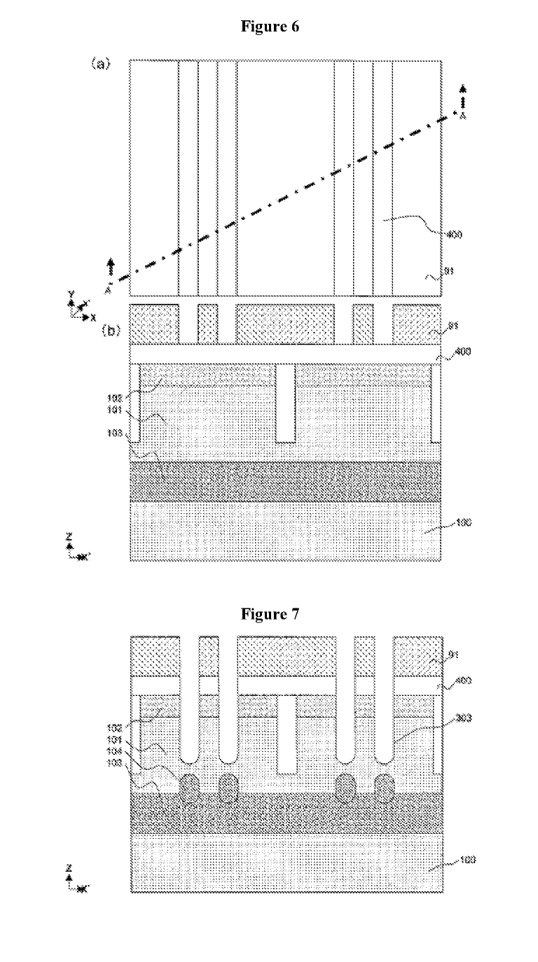

A method of manufacturing the semiconductor device 1 in the second mode of embodiment will now be described with reference to FIG. 6 to FIG. 8.

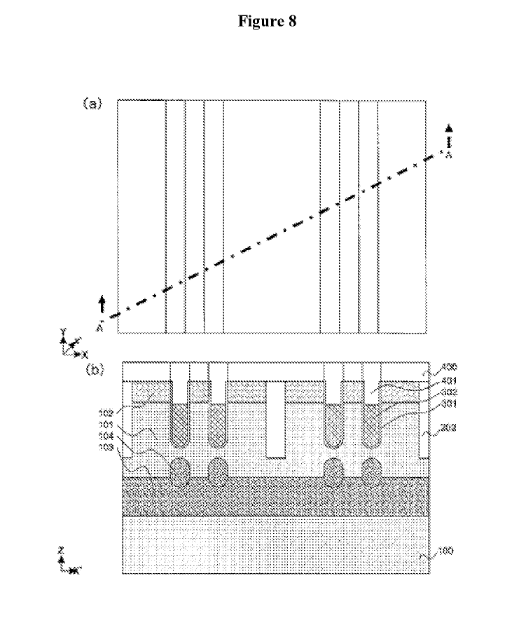

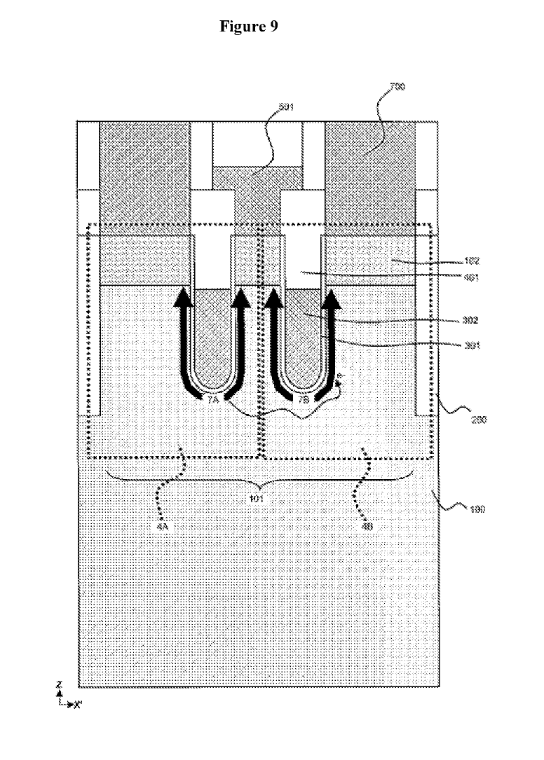

Here, FIG. 6 (b), FIG. 7 and FIG. 8 (b) are cross-sectional views corresponding to FIG. 5 (b), and FIG. 6 (a) and FIG. 8 (a) are plan views corresponding to FIG. 5 (a).

First, as illustrated in FIG. 6, the same steps as in the first mode of embodiment are followed as far as the deposition of the first interlayer insulating film 400 over the entire surface of the semiconductor substrate 100.

A resist 91 is then applied over the entire surface of the semiconductor substrate 100, and a pattern of word trenches 303 is formed by lithography. It should be noted that although the pattern of word trenches 303 is formed using the resist 91, it may also be a hardmask pattern employing a method such as double-patterning.

Word trenches 303 are then opened by etching, and an impurity is introduced, at a concentration that is higher than that of the embedded diffusion layer 103, into zones which extend from a location that is L2 (for example 50 nm) deeper than the word trenches 303 and which adjoin the embedded diffusion layer 103, to form the localized embedded diffusion layers 104.

Then, as illustrated in FIG. 8, known methods are used to form the memory cell gate insulating films 301, the word lines 302 and the cap insulating films 401. Further, known methods are used to form the bit lines 502, the second interlayer insulating film 600, the capacitor contact plugs 700, the stopper film 780, the third interlayer insulating film 790, the capacitors 800, the fourth interlayer insulating film 900 and the protective insulating film 930. This completes the semiconductor device 1 in FIG. 5.

As discussed hereinabove, the semiconductor device according to the present invention is characterized in that it is provided with: a plurality of groove portions for element isolation, formed extending in a first direction (Y-direction) in such a way as to divide an element-forming layer, where said element-forming layer has been formed on the surface of a semiconductor substrate; a plurality of first element isolation regions formed by embedding element isolation insulating films into the groove portions for element isolation; a plurality of groove portions for element isolation, formed extending in a second direction (X-direction) in such a way as to divide the element-forming layer; a plurality of second element isolation regions formed by embedding element isolation insulating films into the groove portions for element isolation; a plurality of active regions which are insulated and isolated in the X-direction and the Y-direction by means of the first element isolation regions and the second element isolation regions; an embedded diffusion region having the opposite characteristic to the element-forming layer, in a zone in at least the active region, in a location that is deeper than the first element isolation regions and the second element isolation regions in the element-forming layer; a plurality of groove portions for embedded gates, formed extending in the Y-direction; and gate electrodes embedded in the groove portions for the embedded gates, with the interposition of a gate insulating film; and in that the distance between the embedded diffusion region and the lower ends of the gate electrodes is between 50 nm and 300 nm.

Further, the method of manufacturing a semiconductor device according to the present invention is characterized in that it comprises: a step of forming a plurality of groove portions for element isolation, extending in the X-direction and the Y-direction in such a way as to divide an element-forming layer, and embedding element isolation insulating films into the groove portions to form a plurality of element isolation regions and a plurality of active regions which are insulated and isolated by means of the plurality of element isolation regions; a step of forming embedded diffusion regions by implantation; a step of forming a plurality of groove portions for embedded gates, extending in the Y-direction which intersects the first element isolation regions and the active regions; and a step of forming and embedding gate electrodes in the groove portions for the embedded gates, with the interposition of gate insulating films.

As described hereinabove, in the modes of embodiment of the present invention, a plurality of groove portions for element isolation are formed in such a way as to divide an element-forming layer formed on the surface of a semiconductor substrate, and by embedding element isolation insulating films into these grooves, a plurality of element isolation regions and a plurality of active regions insulated and isolated by means of the plurality of element isolation regions are formed, and an embedded diffusion region is formed in a layer below the element isolation regions.

By this means, electric charge ejected from the channels is absorbed by the embedded diffusion region. In this way, variations in the threshold voltage can be reduced even if the pitch spacing between adjacent gate electrodes (word lines) is reduced, and further miniaturization can therefore be supported.

Further, according to the method of manufacturing the semiconductor device in the present invention, it is possible to manufacture the semiconductor device capable of supporting further miniaturization, discussed hereinabove.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention.

### EXPLANATION OF THE REFERENCE NUMBERS

1 Semiconductor device
91 Resist
100 Semiconductor substrate
101 Memory cell active region
102 Memory cell source/drain diffusion layer
103 Embedded diffusion layer
104 Localized embedded diffusion layer
201 First element isolation region
202 Second element isolation region
301 Memory cell gate insulating film
302 Word line
303 Word trench
400 First interlayer insulating film
401 Cap insulating film
501 Bit line
502 Cover insulating film
503 Liner film
600 Second interlayer insulating film
700 Capacitor contact plug
780 Stopper film
790 Third interlayer insulating film
800 Capacitor
810 Cylinder hole
811 Lower electrode
812 Capacitative insulating film
813 Upper electrode
900 Fourth interlayer insulating film
930 Protective insulating film

1. A semiconductor device comprising:
a plurality of first element isolation regions formed extending in a first direction on a semiconductor substrate;
a plurality of second element isolation regions formed extending in a second direction which intersects the first direction;
a plurality of active regions which are insulated and isolated by means of the first element isolation regions and the second element isolation regions;
a plurality of gate electrodes formed extending in the first direction; and
a first embedded diffusion layer which is formed in a location that is deeper than the first element isolation regions and the second element isolation regions, and which has the opposite characteristic to the active regions.

2. The semiconductor device of claim 1, wherein the first embedded diffusion layer absorbs electric charge ejected from channels formed at the peripheries of the gate electrodes.

3. The semiconductor device of claim 1, wherein the distance between the lower ends of the gate electrodes and the upper end of the first embedded diffusion layer is set to a prescribed distance making it possible for the first embedded diffusion layer to absorb electric charge ejected from the channels.

4. The semiconductor device of claim 3, wherein the prescribed distance is 300 nm.

5. The semiconductor device of claim 1, wherein the first embedded diffusion layer is formed by introducing an impurity having the opposite characteristic to the active regions.

6. The semiconductor device of claim 1, comprising a second embedded diffusion layer having the opposite characteristic to the active regions.

7. The semiconductor device of claim 6, wherein the second embedded diffusion layer absorbs electric charge that was ejected from the channels formed at the peripheries of the gate electrodes but was not absorbed by the first embedded diffusion layer.

8. The semiconductor device of claim 6, wherein the second embedded diffusion layer is formed locally with respect to the first element isolation regions.

9. The semiconductor device of claim 6, wherein the distance between the lower ends of the gate electrodes and the upper end of the second embedded diffusion layer is less than the distance between the lower ends of the gate electrodes and the upper end of the first embedded diffusion layer.

10. The semiconductor device of claim 9, wherein the distance between the lower ends of the gate electrodes and the upper end of the second embedded diffusion layer is 50 nm.

11. The semiconductor device of claim 6, wherein the second embedded diffusion layer is formed by introducing an impurity having the opposite characteristic to the active regions, and the concentration of the impurity introduced into the second embedded diffusion layer is higher than the concentration of the impurity introduced into the first embedded diffusion layer.

12. A method of manufacturing a semiconductor device comprising:
forming a plurality of first groove portions for element isolation extending in a first direction on a semiconductor substrate;
forming a plurality of first element isolation regions by embedding first element isolation insulating films into the first groove portions;
forming a plurality of second groove portions for element isolation extending in a second direction which intersects the first direction;
forming a plurality of second element isolation regions by embedding second element isolation insulating films into the second groove portions;
forming a plurality of active regions which are insulated and isolated in the first direction and the second direction by means of the first element isolation regions and the second element isolation regions;
forming a plurality of groove portions for embedded gates extending in the first direction;
embedding gate electrodes in the groove portions for the embedded gates, with the interposition of gate insulating films; and
forming a first embedded diffusion layer having the opposite characteristic to the active regions in a location that is deeper than the first element isolation regions and the second element isolation regions.

13. The method of claim 12, wherein the first embedded diffusion layer absorbs electric charge ejected from channels formed at the peripheries of the gate electrodes.

14. The method of claim 12, wherein the distance between the lower ends of the gate electrodes and the upper end of the first embedded diffusion layer is set to a prescribed distance making it possible for the first embedded diffusion layer to absorb electric charge ejected from the channels.

15. The method of claim 14, wherein the prescribed distance is 300 nm.

16. The method of claim 12, wherein the first embedded diffusion layer is formed by introducing an impurity having the opposite characteristic to the active regions.

17. The method of claim 12, wherein a second embedded diffusion layer having the opposite characteristic to the active regions is additionally formed.

18. The method of claim 17, wherein the second embedded diffusion layer absorbs electric charge that was ejected from the channels formed at the peripheries of the gate electrodes but was not absorbed by the first embedded diffusion layer.

19. The method of claim 17, wherein the second embedded diffusion layer is formed locally with respect to the first element isolation regions.

20. The method of claim 17, wherein the distance between the lower ends of the gate electrodes and the upper end of the second embedded diffusion layer is less than the distance between the lower ends of the gate electrodes and the upper end of the first embedded diffusion layer.

21. The method of claim 20, wherein the distance between the lower ends of the gate electrodes and the upper end of the second embedded diffusion layer is 50 nm.

22. The method of claim 17, wherein the second embedded diffusion layer is formed by introducing an impurity having the opposite characteristic to the active regions, and the concentration of the impurity introduced into the second embedded diffusion layer is higher than the concentration of the impurity introduced into the first embedded diffusion layer.
